(19) United States
(12) Patent Application Publication
(10) Pub. No.: US 2006/0120188 A1
(43) Pub. Date: Jun. 8, 2006

(54) Defect detection circuit

(75) Inventors: Nobuyuki Mitsui, Itami-shi (JP); Motonori Taniguchi, Kyoto-shi (JP)

Correspondence Address: STEPTOE & JOHNSON LLP, 1330 CONNECTICUT AVE., NW, WASHINGTON, DC, 20036, US

(73) Assignee: Matsushita Electric Industrial Co., LTD., Kadoma-shi (JP)

(21) Appl. No.: 11/261,639

(22) Filed: Oct. 31, 2005

(30) Foreign Application Priority Data
Nov. 18, 2004 (JP) 2004-333808

(51) Int. Cl. G11C 29/00; G11C 7/00

(52) U.S. Cl. 365/201

(57) ABSTRACT

A defect detection circuit capable of accurately detecting a defect existing in correspondence with a time period in which the operation of an optical disk unit is changed from recording operation to reproducing operation or from reproducing operation to recording operation. When the operation of the optical disk unit is changed, a mono-multi circuit outputs a signal MM1 for turning on the switch in an integration circuit to reduce the time constant of the integration circuit. A logic circuit is supplied with a defect detection circuit DD output from a comparator and the output signal MM1 from the mono-multi circuit, executes a computation to make ineffective the signal MM1 during a time period during which the defect detection signal DD indicates the existence of a defect, and outputs a signal CP to the switch in the integration circuit.

### FIELD OF THE INVENTION

The present invention relates to a defect detection circuit for detecting a defect on an optical disk.

### BACKGROUND OF THE INVENTION

In recent years, with the remarkable increase in amount of information, optical disk units having a large capacity, having a high read/write speed and capable of random access have been put to use as information data recording/reproduction devices in computer systems. As recording media, optical disks such as a compact disc-recordable (CD-R), a CD-rewritable (CD-RW), a digital versatile disc-recordable/rewritable (DVD-R/RW) and a DVD-random access memory (DVD-RAM) are being used.

Such optical disk units incorporate a defect detection circuit for detecting a defect in an optical disk which defines a region in the optical disk where write or read is not normally performed. The defect detection circuit detects a defect by detecting a change in an envelope of a reflection signal obtained in response to the intensity of reflected light obtained from a light beam applied to and converged on the optical disk, and outputs a defect detection signal indicating the existence/nonexistence of a defect (see, for example, Japanese Patent Laid-Open No. 2003-196853).

The defect detection signal is used, for example, as a signal for holding a preceding value in a tracking servo circuit for making a laser spot follow a center of a track on an optical disk and a focus servo circuit for focusing of a laser spot on a disk recording surface, and as a signal for obtaining an extracted signal for determination of a recording impossible region of an optical disk in a central processing unit (CPU) for various kinds of control incorporated in an optical disk unit.

A conventional defect detection circuit will be described with reference to FIG. 5 showing the configuration of the defect detection circuit. Referring to FIG. 5, a variable-gain amplifier 1 amplifies a reflection signal AS generated from reflected light obtained from a light beam applied to an optical disk at a predetermined gain according to a recording gate signal WTGT indicating whether the present operation of the optical disk unit incorporating the defect detection circuit is recording operation or reproducing operation, and outputs the amplified signal. The following description is made by assuming that the signal level of the recording gate signal WTGT becomes high level when recording operation is performed and becomes low level when reproducing operation is performed.

A high-speed envelope detection circuit 2 detects an envelope of the reflection signal AS amplified by the variable-gain amplifier 1 (hereinafter referred to as “amplifier output signal AP”) and outputs an envelope signal.

An integration circuit 3 integrates the envelope signal EM from the high-speed envelope detection circuit 2 with a variable time constant and outputs a signal IS. As shown in FIG. 5, the integration circuit 3 has a resistor 4, a capacitor 5, and a switch 6 connected in parallel with the resistor 4. The envelope signal EM is applied to one end of the resistor 4. The other end of the resistor 4 is connected to a slice level setting circuit 7 and to one end of the capacitor 5. The other end of the capacitor 5 is grounded.

The switch 6 is controlled by a pulse signal MM2 of a certain duration output from a mono-multi circuit 10. The switch 6 is set so as to be on when the level of the pulse signal MM2 is high level, and off when level of the pulse signal MM2 is low level. The time constant of the integration circuit 3 can be changed by turning on or off the switch 6. That is, the time constant of the integration circuit 3 when the switch 6 is on is smaller than a predetermined time constant determined by the resistor 4 and the capacitor 5.

The slice level setting circuit 7 sets a slice level SD for detection of a defect on an optical disk with reference to the output signal IS from the integration circuit 3. A comparator 8 compares the slice level SD and the level of the envelope signal EM output from the high-speed envelope detection circuit 2 and generates a defect detection signal DD indicating the existence/nonexistence of a defect.

An edge detection circuit 9 detects from a change in level of the recording gate signal WTGT a change in the operation of the optical disk unit from recording operation to reproducing operation or from reproducing operation to recording operation, and outputs a detection signal. The mono-multi circuit 10 receives the detection signal output from the edge detection circuit 9 and outputs the pulse signal MM2 of the certain duration to the integration circuit 3.

The operation of the thus-arranged conventional defect detection circuit will be described with reference to FIGS. 5 and 6. FIG. 6 shows the waveforms of the output signals in the defect detection circuit.

In ordinary cases of recoding on optical disks in optical disk units, data is recorded, for example, by reading out address information recorded on the optical disk and by searching for a target address region. That is, reproducing operation and recording operation are repeated during data recording. Since the intensity of light beam applied to an optical disk during recording operation and the intensity of light beam applied to the optical disk during reproducing operation are different from each other, reflection signal AS changed in signal level as shown in FIG. 6 is input to the variable-gain amplifier 1 during data recording.

The variable-gain amplifier 1 amplifies the reflection signal AS at a predetermined gain according to the operation of the optical disk unit on the basis of the recording gate signal WTGT to equalize the level of the amplifier output signal AP between recording operation and reproducing operation in order to prevent a difference in level of the reflection signal AS from being detected as a change in the envelop.

In a case where the variable gain amplifier 1 does not have the suitable set gain due to a variation in the gain setting for example, a difference in level occurs in the amplifier output signal AP between recording operation and reproducing operation, as shown in FIG. 6.

The high-speed envelope detection circuit 2 detects the envelope of the input amplifier output signal AP and outputs the envelope signal EM to the integration circuit 3 and to the comparator 8. The integration circuit 3 integrates the envelope signal EM from the high-speed envelope detection circuit 2 and outputs the signal IS to the slice level setting circuit 7.

After the operation of the optical disk unit has been changed from reproducing operation to recording operation, or during a certain time period t2 after the operation of the optical disk unit has been changed from recording operation to reproducing operation, the integration circuit 3 integrates the envelope signal EM by performing an operation for reducing the time constant as described below.

First, the edge detection circuit 9 detects a change in level of the recording gate signal WTGT from low level to high level or from high level to low level, and outputs the detection signal to the mono-multi circuit 10.

The mono-multi circuit 10 receives the detection signal from the edge detection circuit 9, generates pulse signal MM2 having the high signal level during the certain time period t2, and outputs the pulse signal MM2 to the switch 6 in the integration circuit 3.

In response to the change to high level of the pulse signal MM2 from the mono-multi circuit 10, the switch 6 becomes on. When the switch 6 becomes on, the resistor 4 is shorted to reduce the time constant of the integration circuit 3. During the time period t2 during which the level of the pulse signal MM2 from the mono-multi circuit 10 is high level, therefore, the integration circuit 3 integrates the envelope signal EM with a time constant smaller than the normal value and outputs the output signal IS to the slice level setting circuit 7 in the following stage.

During periods other than the certain period t2, the level of the pulse signal from the mono-multi circuit 10 is low level and the switch 6 in the integration circuit 3 is off. Under this condition, the integration circuit 3 integrates the envelope signal EM with the predetermined time constant determined by the resistor 4 and the capacitor 5 and outputs the output signal IS to the slice level setting circuit 7 in the following stage.

The slice level setting circuit 7 sets the slice level SD by converting the level of the output signal IS from the integration circuit 3 and outputs the slice level SD to the comparator 8. The comparator 8 binarizes the envelope signal EM output from the high-speed envelope detection circuit 2 with reference to the slice level SD and outputs the binarized signal as defect detection signal DD.

That is, during periods other than the certain period t2, the envelope signal EM is integrated with the predetermined time constant; a change in waveform of the output signal IS from the integration circuit 3 follows a change in waveform of the envelope signal EM with a delay from the same; and the level of the envelope signal EM becomes lower than the slice level SD at a defect to form a defect signal TSI (true defect signal) indicating the existence of the defect, the defect signal TSI being output during the period corresponding to the defect as a defect detection signal DD.

In a case where a change in level of the envelope signal EM occurs between reproducing operation and recording operation due to a variation in the gain setting of the variable-gain amplifier 1 for example, the level of the envelope signal EM also becomes lower than the slice level SD after the operation of the optical disk unit has been changed from recording operation to reproducing operation, as shown in FIG. 6. In this defect detection circuit, however, the envelope signal EM is integrated by reducing the time constant of the integration circuit 3 during the certain time period t2 after changing from recording operation to reproducing operation. Therefore, the change in waveform of the output signal IS from the integration circuit 3 can rapidly follow the change in waveform of the envelope signal EM so that the time period during which the defect signal FSI (false defect signal) is output is shorter than the time period during which the defect signal TSI is output.

Accordingly, settings are made in the tracking servo circuit, the focus servo circuit and the CPU such that false defect signals of a short output duration are not used, thus realizing an accurate tracking servo operation or the like even in a case where a change in level of the envelope signal EM occurs between reproducing operation and recording operation due to a variation in the gain setting of the variable amplifier 1 for example.

However, the conventional defect detection circuit has a problem described below. In a case where a detect exists in correspondence with a time period in which change from recording operation to reproducing operation is made as shown in FIG. 7, the time constant of the integration circuit 3 is reduced during the time period corresponding to the defect and the output signal IS from the integration circuit 3 rapidly follows the change in waveform of the envelope signal EM. The time period during which the level of the envelope signal EM is lower than the slice level SD is thereby reduced with respective to the defect (i.e. the time period during which the defect signal indicating the existence of the defect is output is reduced with respect to an actual defect region), resulting in failure to accurately detect the defect. In this case, the tracking servo circuit and the focus servo circuit for example become unable to output the previous-value-holding signal during the time period corresponding to the actual defect region, resulting in hindrance to achieving stable data access. The same problem also exists with a case where a defect exists in correspondence with a time period in which the operation of the optical disk unit is changed from reproducing operation to recording operation.

### DISCLOSURE OF THE INVENTION

In view of the above-described problem, an object of the present invention is to provide a defect detection circuit capable of accurately detecting a defect existing in correspondence with a time period in which the operation of an optical disk unit is changed from recording operation to reproducing operation or from reproducing operation to recording operation, by making ineffective a signal for turning on a switch during the time period corresponding to the existence of a defect (a signal for reducing a time constant).

To achieve the above-described object, according to a first aspect of the present invention, there is provided a defect detection circuit incorporated in an optical disk unit which makes data access to an optical disk, the defect detection circuit including an amplification device which amplifies a reflection signal generated from reflected light obtained from a light beam applied to the optical disk at a gain according to a recording gate signal indicating whether the present operation of the optical disk unit is recording operation or reproducing operation, and which outputs the amplified signal, an envelope detection device which detects an envelope of the reflection signal amplified by the amplification device, and which outputs an envelope signal, an integration device which integrates the envelope signal from the envelope detection device with a variable time constant, and which outputs a signal as a result of the integration, a slice level setting device which sets a slice level for detection of a defect on the optical disk with reference to the output signal from the integration device, a defect detection signal generation device which compares the level of the envelope signal from the envelope detection device and the slice level, and which generates a defect detection signal indicating the existence/nonexistence of a defect, an operation change detection device which detects from the recording gate signal a change in the operation of the optical disk unit from recording operation to reproducing operation or from reproducing operation to recording operation, and which outputs a detection signal, a mono-multi device which receives the detection signal from the operation change detection device and outputs the signal for reducing the time constant of the integration device for a predetermined time period, and a computation device which is supplied with the signal for reducing the time constant and the defect detection signal, which performs a computation on the signal for reducing the time constant and the defect detection signal to make ineffective the signal for reducing the time constant during a time period during which the defect detection signal indicates the existence of a defect, and which outputs the signal for reducing the time constant after the computation to the integration device.

According to a second aspect of the present invention, there is provided a defect detection circuit incorporated in an optical disk unit which makes data access to an optical disk, the defect detection circuit including an amplification device which amplifies a reflection signal generated from reflected light obtained from a light beam applied to the optical disk at a gain according to a recording gate signal indicating whether the present operation of the optical disk unit is recording operation or reproducing operation, and which outputs the amplified signal, an envelope detection device which detects an envelope of the reflection signal amplified by the amplification device, and which outputs an envelope signal, an integration device which integrates the envelope signal from the envelope detection device with a variable time constant, and which outputs a signal as a result of the integration, a slice level setting device which sets a slice level for detection of a defect on the optical disk with reference to the output signal from the integration device, a defect detection signal generation device which compares the level of the envelope signal from the envelope detection device and the slice level, and which generates a defect detection signal indicating the existence/nonexistence of a defect, an operation change detection device which detects from the recording gate signal a change in the operation of the optical disk unit from recording operation to reproducing operation or from reproducing operation to recording operation, and which outputs a detection signal, a mono-multi device which receives the detection signal from the operation change detection device and outputs the signal for reducing the time constant of the integration device for a predetermined time period, a holding device which holds the level of the envelope signal when the operation of the optical disk unit is reproducing operation, a level-shift device which shifts the level held by the holding device by a certain value selected as desired and outputs the shifted level, a comparison device which compares the level of the envelope signal from the envelope detection device and the level from the level-shift device and outputs a comparison result signal indicating the existence/nonexistence of a defect on the optical disk, and a computation device which is supplied with the signal for reducing the time constant and the comparison result signal, which performs a computation on the signal for reducing the time constant and the comparison result signal to make ineffective the signal for reducing the time constant during a time period during which the comparison result signal indicates the existence of a defect, and which outputs the signal for reducing the time constant after the computation to the integration device.

According to the present invention, the signal for reducing the time constant of the integration device is made ineffective during a time period corresponding to the existence of a defect to enable a defect existing in correspondence with a time period in which the operation of the optical disk unit is changed from recording operation to reproducing operation or from reproducing operation to recording operation to be detected with high accuracy.

### BRIEF DESCRIPTION OF THE DRAWINGS

FIG. 1 is a block diagram showing a configuration of a defect detection circuit in Embodiment 1 of the present invention;

FIG. 2 is a diagram showing waveforms of output signals in the defect detection circuit in Embodiment 1;

FIG. 3 is a block diagram showing a configuration of a defect detection circuit in Embodiment 2of the present invention;

FIG. 4 is a diagram showing waveforms of output signals in the defect detection circuit in Embodiment 2;

FIG. 5 is a block diagram showing a configuration of a conventional defect detection circuit;

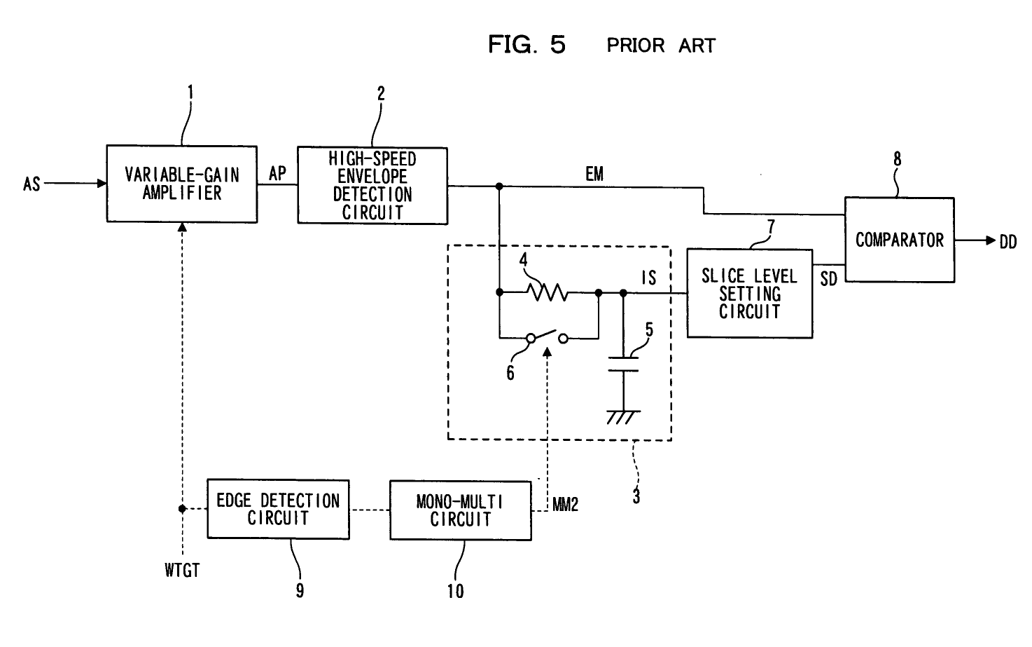

FIG. 6 is a diagram showing waveforms of output signals in the conventional defect detection circuit; and

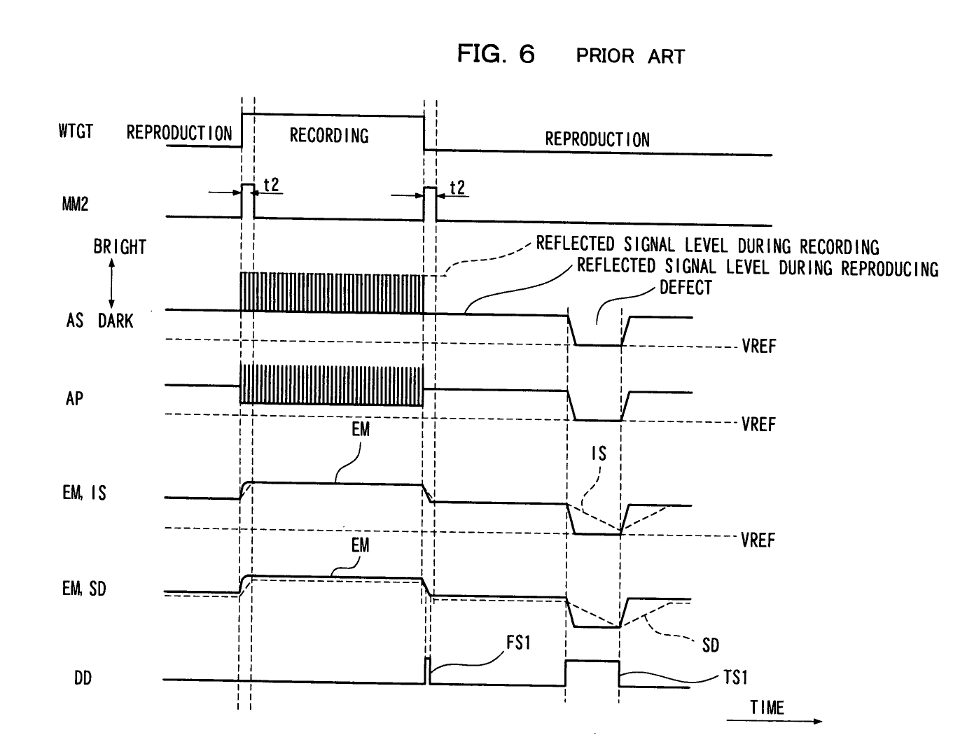

FIG. 7 is a diagram showing waveforms of output signals in the conventional defect detection circuit.

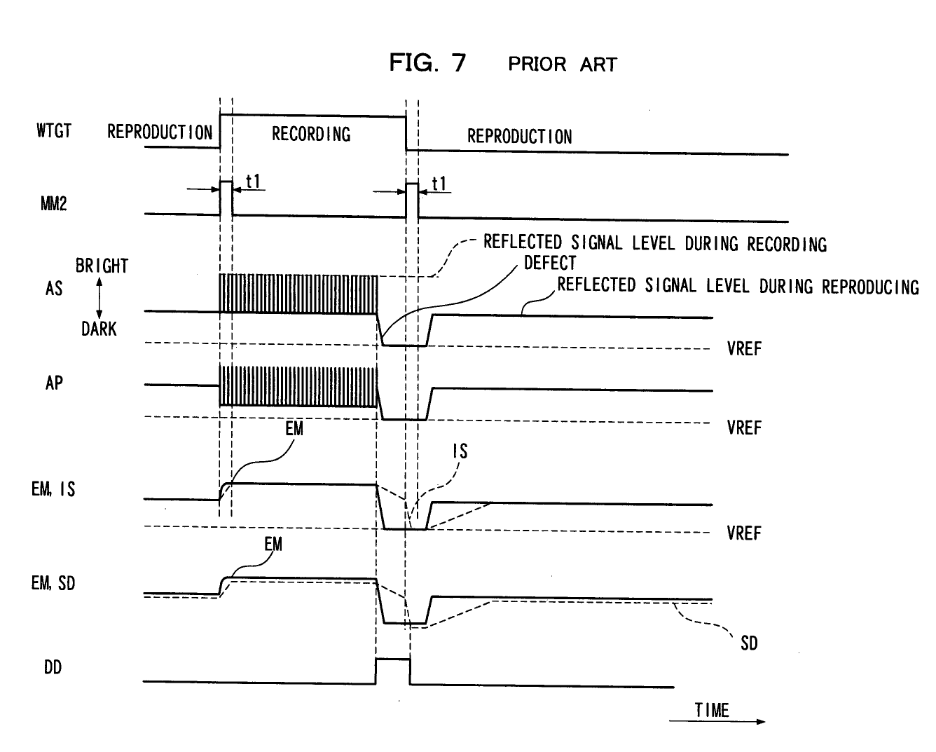

### DESCRIPTION OF THE EMBODIMENTS

Defect detection circuits in embodiments of the present invention will be described below.

### Embodiment 1

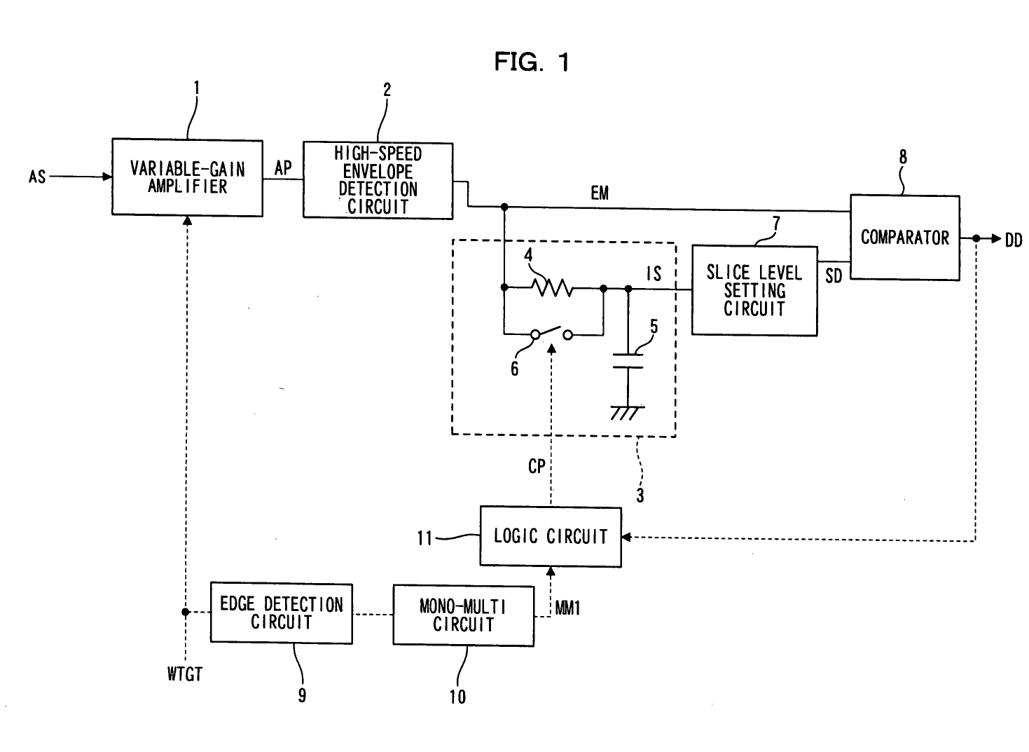

FIG. 1 is a block diagram showing the configuration of a defect detection circuit in Embodiment 1 of the present invention. The defect detection circuit is incorporated in an optical disk unit for performing at least data recording on an optical disk.

Referring to FIG. 1, a variable-gain amplifier (amplification device) 1 amplifies a reflection signal AS generated from reflected light obtained from a light beam applied to an optical disk at a predetermined gain according to a recording gate signal WTGT indicating whether the present operation of the optical disk unit incorporating the defect detection circuit is recording operation or reproducing operation, and outputs the amplified signal. The following description is made by assuming that the signal level of the recording gate signal WTGT becomes high level when recording operation is performed and becomes low level when reproducing operation is performed.

A high-speed envelope detection circuit (envelope detection device) 2 detects an envelope of the reflection signal AS (amplifier output signal AP) amplified by the variable-gain amplifier 1 and outputs an envelope signal EM. The high-speed envelope detection circuit 2, which is an ordinary detection circuit, obtains an upper envelope of the amplifier output signal AP from the variable-gain amplifier and outputs the envelope signal.

An integration circuit (integration device) 3 integrates the envelope signal EM from the high-speed envelope detection circuit 2 with a variable time constant and outputs a signal IS. As shown in FIG. 1, the integration circuit 3 has a resistor 4, a capacitor 5, and a switch 6 connected in parallel with the resistor 4. The envelope signal EM is applied to one end of the resistor 4. The other end of the resistor 4 is connected to a slice level setting circuit 7 and to one end of the capacitor 5. The other end of the capacitor 5 is grounded.

The switch 6 is controlled by a computation output signal CP output from a logic circuit 11 described below. The time constant of the integration circuit 3 can be changed by turning on or off the switch 6. That is, the time constant of the integration circuit 3 when the switch 6 is on is smaller than a predetermined time constant determined by the resistor 4 and the capacitor 5.

The slice level setting circuit (slice level setting device) 7 sets a slice level SD for detection of a defect on an optical disk with reference to the output signal IS from the integration circuit 3.

A comparator (defect detection signal generation device) 8 compares the slice level SD and the level of the envelope signal EM output from the high-speed envelope detection circuit 2 and generates a defect detection signal DD indicating the existence/nonexistence of a defect. The following description is made by assuming that the level of the defect detection signal DD is high level during a time period during which the existence of a defect is indicated, and is low level during other time periods.

An edge detection circuit (operation change detection device) 9 detects from a change in level of the recording gate signal WTGT a change in the operation of the optical disk unit from recording operation to reproducing operation or from reproducing operation to recording operation, and outputs a detection signal.

A mono-multi circuit (mono-multi device) 10 receives the detection signal output from the edge detection circuit 9 and outputs a mono-multi signal MM1 for turning on the switch 6 (a signal for reducing the time constant of the integration circuit 3) to the integration circuit 3 during a certain time period. The description will be made by assuming that the mono-multi signal MM1 is a pulse signal, and that the switch 6 is on when this pulse signal is high level.

A logic circuit (computation device) 11 is supplied with the mono-multi signal MM1 from the mono-multi circuit 10 and the defect detection signal DD from the comparator 8, performs computation such that the mono-multi signal MM1 is made ineffective during a time period during which the defect detection signal DD indicates the existence of a defect, and outputs the computation output signal CP to the integration circuit 3.

More specifically, the logic circuit 11 outputs the mono-multi signal MM1 as the computation output signal CP when the level of the defect detection signal DD is low level, and fixes the level of the computation output signal CP at low level when the defect detection signal DD is high level (during a time period during which the existence of a defect is indicated).

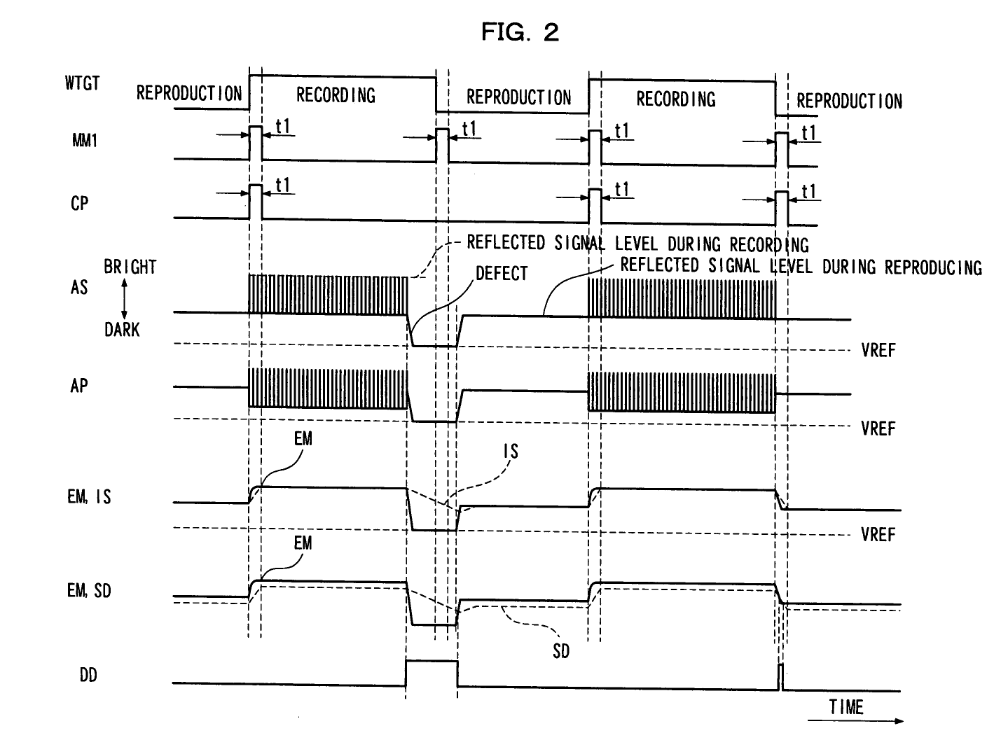

The operation of the thus-arranged defect detection circuit will be described with reference to FIGS. 1 and 2. FIG. 2 shows the waveforms of the output signals in the defect detection circuit. The following description is made with respect to a case where a defect exists in correspondence with a time period in which the operation of the optical disk unit is changed from recording operation to reproducing operation. The same description can also be made with respect to a case where a defect exists in correspondence with a time period in which the operation of the optical disk unit is changed from reproducing operation to recording operation.

First, a plurality of light receiving elements (not shown) receive reflected light obtained from a light beam applied to and converged on an optical disk, convert the light into electrical signals changing in level according to the amount of reflected light, and output the electrical signals. The electrical signals output from the plurality of light receiving elements are added together to obtain a total addition signal, which is input as a reflection signal AS to the variable-gain amplifier 1.

In ordinary cases of recoding on optical disks in optical disk units, data is recorded, for example, by reading out address information recorded on the optical disk and by searching for a target address region. That is, reproducing operation and recording operation are repeated during data recording. Since the intensity of light beam applied to the optical disk during recording operation and the intensity of light beam applied to the optical disk during reproducing operation are different from each other, reflection signal AS changed in signal level as shown in FIG. 2 is input to the variable-gain amplifier 1 during data recording.

When the level of the recording gate signal WTGT input to the variable-gain amplifier 1 is low level, the variable-gain amplifier 1 determines that the present operation of the optical disk unit is reproducing operation, amplifies the reflection signal AS at a gain for reproducing operation, and outputs the amplifier output signal AP.

When the level of the recording gate signal WTGT input to the variable-gain amplifier 1 is high level, the variable-gain amplifier 1 amplifies the reflection signal AS by setting a gain lower than that at the time of reproducing operation and outputs the amplifier output signal AP.

Thus, the variable-gain amplifier 1 amplifies the reflection signal AS at the predetermined gain according to the operation of the optical disk unit on the basis of the recording gate signal WTGT to equalize the level of the amplifier output signal AP between recording operation and reproducing operation in order to prevent a difference in level of the reflection signal AS from being detected as a change in the envelope.

In a case where the variable gain amplifier 1 does not have the suitable set gain due to a variation in the gain setting for example, a difference in level occurs in the amplifier output signal AP between recording operation and reproducing operation, as shown in FIG. 2.

The high-speed envelope detection circuit 2 detects the upper envelope of the input amplifier output signal AP and outputs the envelope signal EM to the integration circuit 3. The integration circuit 3 integrates the envelope signal EM with the predetermined time constant determined by the resistor 4 and the capacitor 5 when the level of the computation output signal CP from the logic circuit 11 is low level. When the level of the computation output signal CP from the logic circuit 11 is high level, switch 6 is turned on and the integration circuit 3 integrates the envelope signal EM with a time constant smaller than the predetermined time constant and outputs the output signal IS to the slice level setting circuit 7 in the following stage.

The slice level setting circuit 7 sets the slice level SD with reference to the output signal IS from the integration circuit 3 and outputs the slice level SD to the comparator 8. The slice level SD is set lower than the level of the envelope signal EM at any non-defective portion of the optical disk and higher than the level of the envelope signal EM at a defect. The comparator 8 binarizes the envelope signal EM output from the high-speed envelope detection circuit 2 with reference to the slice level SD and outputs the binarized signal as defect detection signal DD.

On the other hand, the mono-multi circuit 10 outputs the mono-multi signal MM1 for turning on the switch 6 (pulse signal having high signal level) during a certain time period t1 after the operation of the optical disk unit has been changed from reproducing operation to recording operation, or during a certain time period t1 after the operation of the optical disk unit has been changed from recording operation to reproducing operation.

That is, the edge detection circuit 9 outputs the detection signal to the mono-multi circuit 10 in response to a change in level of the recording gate signal WTGT from low level to high level or from high level to low level. The mono-multi circuit 10 receives the detection signal from the edge detection circuit 9, generates the mono-multi signal MM1 for turning on the switch 6 for the predetermined time period t1, and outputs the mono-multi signal MM1 to the logic circuit 11.

The logic circuit 11 performs a logic operation on the mono-multi signal MM1 and the defect detection signal DD and outputs the mono-multi signal MM1 as computation output signal CP while the defect detection signal DD is not indicating the existence of any detect, i.e., during the time period during which the level of the defect detection signal DD is low level.

Accordingly, if no defect exists in correspondence with a time period in which the operation of the optical disk unit is changed, the mono-multi signal MM1 for turning on the switch 6 is output to the switch 6 in the integration circuit 3.

The switch 6 becomes on when the mono-multi signal MM1 (computation output signal CP) is received from the logic circuit 11. When the switch 6 becomes on, the resistor 4 is shorted to reduce the time constant of the integration circuit 3. Accordingly, while the operation output signal CP by which the switch 6 is turned on (pulse signal having high signal level) is being output from the logic circuit 11, the integration circuit 3 integrates the envelope signal EM with a time constant smaller than the normal value and outputs the output signal IS to the slice level setting circuit 7 in the following stage.

After a lapse of the time period t1 with no change to low level in the level of the computation output signal CP from the logic circuit 11, the level of the mono-multi signal MM1 from the mono-multi circuit 10 becomes low level and the level of the computation output signal CP from the logic circuit 11 also becomes low level to turn off the switch 6 in the integration circuit 3. The integration circuit 3 then integrates the envelope signal EM with the predetermined time constant and outputs the output signal IS to the slice level setting circuit 7.

While the defect detection signal DD is indicating the existence of a defect, i.e., during a time period during which the level of the defect detection signal DD is high level, the logic circuit 11 outputs the computation output signal CP while fixing the level of this signal at low level.

That is, even in a situation where the operation of the optical disk unit is changed and the mono-multi signal MM1 for turning on the switch 6 (signal for reducing the time constant) is output from the mono-multi circuit 10 during the predetermined time period t1, the computation output signal CP having low signal level is output to the switch 6 in the integration circuit 3.

Accordingly, in a case where a defect exists in correspondence with a time period in which the operation of the optical disk unit is changed, the switch 6 maintains the off state by receiving the computation output signal CP from the logic circuit 11 and the integration circuit 3 integrates the envelope signal EM with the predetermined time constant and outputs the output signal IS to the slice level setting circuit 7 in the following stage.

Therefore, if a defect exists in correspondence with a time period in which the operation of the optical disk unit is changed from recording operation to reproducing operation, the envelope signal EM is integrated with the predetermined time constant even during the predetermined time period t1 during which the time constant is to be reduced, the change in waveform of the output signal IS of the integration circuit 3 follows the change in waveform of the envelope signal EM with a delay from the same. As a result, the time period during which the defect signal indicating the existence of the defect is output corresponds to the actual defect region and the defect existing in correspondence with a time period in which change from recording operation to reproducing operation is made can be detected with high accuracy.

Thus, the defect detection circuit in Embodiment 1 makes ineffective the signal for reducing the time constant of the integration circuit during a time period corresponding to the existence of a defect and is therefore capable of accurately detecting a defect existing in correspondence with a time period in which the operation of the optical disk unit is changed from recording operation to reproducing operation or from reproducing operation to recording operation.

### Embodiment 2

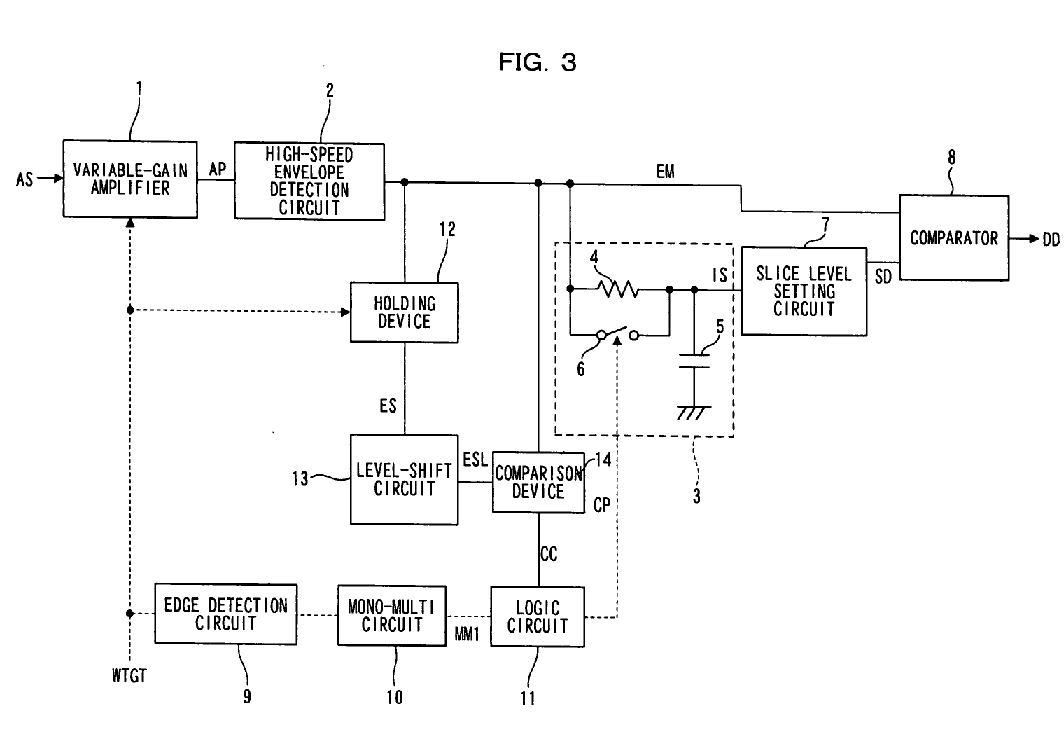

FIG. 3 is a block diagram showing the configuration of a defect detection circuit in Embodiment 2 of the present invention. Components identical or corresponding to those described above with respect to Embodiment 1 are indicated by the same reference numerals, and the description for them will not be repeated.

Referring to FIG. 3, a holding device 12 receives the recording gate signal WTGT, holds the level of the envelope signal EM when the operation of the optical disk unit is reproducing operation, and outputs a hold signal ES. For example, a sample and hold circuit or the like can be used as the holding device 12.

A level-shift circuit (level-shift device) 13 obtains a signal ESL by shifting the hold signal ES output from the holding device 12 (signal level held by the holding device 12) by a certain value selected as desired, and outputs the signal ESL.

A comparison device 14 compares the level of the envelope signal EM and the level of the signal ES output from the level-shift circuit 13 and outputs a comparison result signal CC indicating the existence/nonexistence of a defect on an optical disk. The description will be made by assuming that the comparison result signal CC is a pulse signal which is high level during a time period during which the existence of a defect is indicated, and is low level during other periods.

The logic circuit (computation device) 11 is supplied with the mono-multi signal MM1 from the mono-multi circuit 10 and the comparison result signal CC from the comparison device 14, performs a computation to make the mono-multi signal MM1 ineffective during a time period during which the comparison result signal CC indicates the existence of a defect, and outputs the computation output signal CP to the integration circuit 3.

More specifically, the logic circuit 11 outputs the mono-multi signal MM1 as the computation output signal CP when the level of the comparison result signal CC is low level, and fixes the level of the computation output signal CP at low level when the comparison result signal CC is high level (during a time period during which the existence of a defect is indicated).

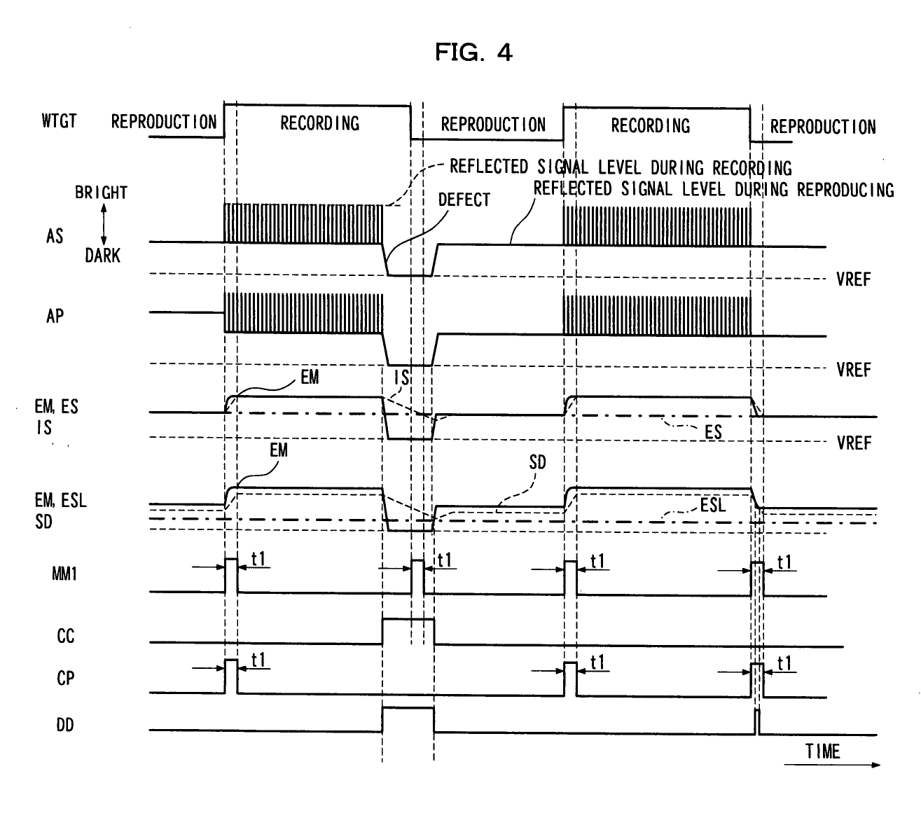

The operation of the thus-arranged defect detection circuit will be described with reference to FIGS. 3 and 4. FIG. 4 shows the waveforms of the output signals in the defect detection circuit. The description will not be repeated for the same operation as that of the defect detection circuit in the Embodiment 1 described above. The following description is made with respect to a case where a defect exists in correspondence with a time period in which the operation of the optical disk unit is changed from recording operation to reproducing operation. The same description can also be made with respect to a case where a defect exists in correspondence with a time period in which the operation of the optical disk unit is changed from reproducing operation to recording operation.

This defect detection circuit differs from the defect detection circuit in Embodiment 1 in the operation to make ineffective the mono-multi signal MM1 for turning on the switch 6 in a case where a defect exists in correspondence with a time period in which the operation of the optical disk unit is changed from recording operation to reproducing operation.

That is, the holding device 12 receives the recording gate signal WTGT, holds the level of the envelope signal EM when the operation of the optical disk unit is reproducing operation, and outputs the hold signal ES to the level-shift circuit 13 in the following stage.

The level-shift circuit 13 outputs the signal ESL obtained by level shifting the hold signal ES by a certain value selected as desired. More specifically, the level-shift circuit 13 shifts the hold signal ES so that the level of the envelope signal EM is lower than that of the ESL signal when a defect exists, and is higher than that of the ESL signal when no defect exists.

The comparison device 14 compares the level of the signal ESL and the level of the envelope signal EM and outputs the pulse signal (comparison result signal) CC, the level of which becomes high level when the level of the envelope signal EM is lower than the level of the signal ESL, and becomes low level when the level of the envelope signal EM is higher than the level of the signal ESL, to the logic circuit 11 in the following stage.

The logic circuit 11 performs a logic operation on the mono-multi signal MM1 from the mono-multi circuit 10 and the pulse signal CC from the comparison device 14 and outputs the mono-multi signal MM1 as computation output signal CP to the switch 6 in the integration circuit 3 while the pulse signal CC is not indicating the existence of any detect, i.e., during the time period during which the level of the pulse signal CC is low level.

During a time period during which the pulse signal CC indicates the existence of a defect, that is, the level of the pulse signal CC is high level, the logic circuit 11 outputs the computation output signal CP while fixing the level of this signal at low level.

Thus, in a case where a defect exists in correspondence with a time period in which the operation of the optical disk unit is changed from recording operation to reproducing operation, the same operation as that in Embodiment 1 is performed. That is, the integration circuit 3 integrates the envelope signal EM with the predetermined time period even during the predetermined time period t1 during which the time constant of the integration circuit 3 is to be reduced, and the change in waveform of the output signal IS of the integration circuit 3 follows the change in waveform of the envelope signal EM with a delay from the same. As a result, the time period during which the defect signal indicating the existence of the defect is output corresponds to the actual defect region and the defect existing in correspondence with a time period in which change from recording operation to reproducing operation is made can be detected with high accuracy (see FIG. 4).

Thus, in the defect detection circuit in Embodiment 2, the level of the envelope signal EM when the operation of the optical disk unit is reproducing operation is held; it is determined that a defect exists when the level of the envelope signal becomes lower than a signal level relating to the held level; and the signal for reducing the time constant of the integration circuit is made ineffective during the time period corresponding to the existence of the defect. The defect detection circuit is therefore capable of detecting with high accuracy a defect existing in correspondence with a time period in which the operation of the optical disk unit is changed from recording operation to reproducing operation or from reproducing operation to recording operation.

According to Embodiment 1or 2, a defect existing in correspondence with a time period in which the operation of the optical disk unit is changed from recording operation to reproducing operation or from reproducing operation to recording operation can be detected with high accuracy. For example, the tracking servo circuit and the focus servo circuit in the optical disk unit can, therefore, output the preceding-value-holding signal during the time period corresponding to the actual defect region, and the CPU can determine a recording impossible region on the optical disk with accuracy. Thus, the operation of the optical disk unit can be stabilized in access to data on the optical disk.

The defect detection circuit in accordance with the present invention can detect a defect on an optical disk with high accuracy and stabilize data recording and reproduction in an optical disk unit or the like and is useful in an optical disk unit and other apparatuses.

What is claimed is:

1. A defect detection circuit incorporated in an optical disk unit which makes data access to an optical disk, the defect detection circuit comprising:
an amplification device for amplifying a reflection signal at a gain according to a recording gate signal indicating whether the present operation of the optical disk unit is recording operation or reproducing operation, and outputting the amplified signal, said reflection signal being generated from reflected light obtained from a light beam applied to the optical disk;
an envelope detection device for detecting an envelope of the reflection signal amplified by the amplification device, and outputting an envelope signal;
an integration device for integrating the envelope signal from the envelope detection device with a variable time constant, and outputting a signal as a result of the integration;
a slice level setting device for setting a slice level for detection of a defect on the optical disk with reference to the output signal from the integration device;
a defect detection signal generation device for comparing the level of the envelope signal from the envelope detection device and the slice level, and generating a defect detection signal indicating the existence/nonexistence of a defect;
an operation change detection device for detecting from the recording gate signal a change in the operation of the optical disk unit from recording operation to reproducing operation or from reproducing operation to recording operation, and outputting a detection signal;
a mono-multi device for receiving the detection signal from the operation change detection device, and outputting the signal for reducing the time constant of the integration device for a predetermined time period; and
a computation device for inputting thereinto the signal for reducing the time constant and the defect detection signal, performing a computation on the signal for reducing the time constant and the defect detection signal to make ineffective the signal for reducing the time constant during a time period during which the defect detection signal indicates the existence of a defect, and outputting the signal for reducing the time constant after the computation to the integration device.

2. A defect detection circuit incorporated in an optical disk unit which makes data access to an optical disk, the defect detection circuit comprising:
an amplification device for amplifying a reflection signal at a gain according to a recording gate signal indicating whether the present operation of the optical disk unit is recording operation or reproducing operation, and outputting the amplified signal, said reflection signal being generated from reflected light obtained from a light beam applied to the optical disk;
an envelope detection device for detecting an envelope of the reflection signal amplified by the amplification device, and outputting an envelope signal;
an integration device for integrating the envelope signal from the envelope detection device with a variable time constant, and outputting a signal as a result of the integration;
a slice level setting device for setting a slice level for detection of a defect on the optical disk with reference to the output signal from the integration device;
a defect detection signal generation device for comparing the level of the envelope signal from the envelope detection device and the slice level, and generating a defect detection signal indicating the existence/nonexistence of a defect;
an operation change detection device for detecting from the recording gate signal a change in the operation of the optical disk unit from recording operation to reproducing operation or from reproducing operation to recording operation, and outputting a detection signal;
a mono-multi device for receiving the detection signal from the operation change detection device, and outputting the signal for reducing the time constant of the integration device for a predetermined time period;
a holding device for holding the level of the envelope signal when the operation of the optical disk unit is reproducing operation;
a level-shift device for shifting the level held by the holding device by a certain value selected as desired, and outputting the shifted level;
a comparison device for comparing the level of the envelope signal from the envelope detection device and the level from the level-shift device, and outputting a comparison result signal indicating the existence/nonexistence of a defect on the optical disk; and
a computation device for inputting thereinto the signal for reducing the time constant and the comparison result signal, performing a computation on the signal for reducing the time constant and the comparison result signal to make ineffective the signal for reducing the time constant during a time period during which the comparison result signal indicates the existence of a defect, and outputting the signal for reducing the time constant after the computation to the integration device.
